(19) United States
(12) Patent Application Publication
(10) Pub. No.: US 2025/0201324 A1
(43) Pub. Date: Jun. 19, 2025

(54) MEMORY DEVICE INCLUDING DAMAGE DETECTION CIRCUIT AND TEST SYSTEM INCLUDING THE MEMORY DEVICE

(71) Applicant: SAMSUNG ELECTRONICS CO., LTD., Suwon-si (KR)

(72) Inventors: Eunji Kim, Suwon-si (KR); Wandong Kim, Suwon-si (KR); Byongmo Moon, Suwon-si (KR); Kwangjin Lee, Suwon-si (KR)

(73) Assignee: SAMSUNG ELECTRONICS CO., LTD., Suwon-si (KR)

(21) Appl. No.: 18/830,032

(22) Filed: Sep. 10, 2024

(30) Foreign Application Priority Data
Dec. 19, 2023 (KR) 10-2023-0186148

(51) Int. Cl. G11C 29/10

(52) U.S. Cl. CPC G11C 29/10

(57) ABSTRACT

A memory device includes a memory cell array region including a plurality of memory cells, a first test pattern form disposed below a bonding pad and configured to output a first test output signal, a second test pattern form disposed below a non-bonding pad and configured to output a second test output signal, and a damage detection circuit. The damage detection circuit is configured to output a test result signal indicating whether a lower region of the bonding pad has been damaged. The test result signal is based on the number of times a logic level of the first test output signal transitions and the number of times a logic level of the second test output signal transitions.

### CROSS-REFERENCE TO RELATED APPLICATION

This application is based on and claims priority under 35 U.S.C. § 119 to Korean Patent Application No. 10-2023-0186148, filed on Dec. 19, 2023, in the Korean Intellectual Property Office, the disclosure of which is incorporated by reference herein in its entirety.

### BACKGROUND

The present disclosure relates to a memory device including a damage detection circuit and a test system including the memory device, and more particularly, to a memory device that uses a damage detection circuit to test whether a lower region of a pad in the memory device has been damaged and outputs a test result.

To connect a memory device to an external device, a pad of the memory device may be electrically connected to the external device through wire bonding. In addition, the memory device may be tested through automated test equipment (ATE). For example, the memory device may be tested by bringing a probe of the ATE into contact with the pad of the memory device. At this time, the lower region of the pad of the memory device may be damaged due to external force generated in the process of performing wire bonding between the pad of the memory device and the external device or bringing the probe of the test equipment into contact with the pad of the memory device. Since damage to the lower region of the pad of the memory device may reduce yield and quality in producing memory devices, there is a need for a method of detecting damage to the lower region of the pad of the memory device at an early stage.

### SUMMARY

One or more embodiments provide a method of detecting damage to a lower region of a pad of a memory device at an early stage.

The aspects of the disclosure are not limited to the above aspect, and other aspects that are not mentioned herein will be clearly understood by those of ordinary skill in the art from the following description.

According to an aspect of the disclosure, a memory device includes: a memory cell array region including a plurality of memory cells; a plurality of bonding pads partially overlapping the memory cell array region in a vertical direction, the plurality of bonding pads including a bonding pad configured to electrically connect the memory device to an external device and a non-bonding pad configured to be electrically connected to an internal circuit of the memory device; a first test pattern form below the bonding pad and configured to output a first test output signal based on a test input signal; a second test pattern form below the non-bonding pad and configured to output a second test output signal based on the test input signal; and a damage detection circuit configured to output a test result signal indicating whether a lower region of the bonding pad has been damaged, based on a first number of logic level transitions of the first test output signal and a second number of logic level transitions of the second test output signal.

According to an aspect of the disclosure, a memory device includes: a memory cell array region including a plurality of memory cells; a plurality of bonding pads partially overlapping the memory cell array region in a vertical direction, the plurality of bonding pads including a bonding pad configured to electrically connect the memory device to an external device and a non-bonding pad configured to be electrically connected to an internal circuit of the memory device; a first test pattern form disposed below the bonding pad and configured to output a first test output signal based on a test input signal; a second test pattern form disposed below the non-bonding pad and configured to output a second test output signal based on the test input signal; and a damage detection circuit configured to output a test result signal indicating whether a lower region of the bonding pad has been damaged, based on comparing a first delay time of the first test output signal with a second delay time of the second test output signal.

According to an aspect of the disclosure, a test system includes: a memory device; and a test device configured to provide a test input signal to the memory device, wherein the memory device is configured to provide, to the test device, a test result signal generated based on the test input signal, and the memory device includes: a memory cell array region including a plurality of memory cells; a plurality of bonding pads partially overlapping the memory cell array region in a vertical direction, the plurality of bonding pads including a bonding pad configured to electrically connect the memory device to an external device and a non-bonding pad configured to be electrically connected to an internal circuit of the memory device; a first test pattern form disposed below the bonding pad and configured to output a first test output signal based on the test input signal; a second test pattern form disposed below the non-bonding pad and configured to output a second test output signal based on the test input signal; and a damage detection circuit configured to output the test result signal indicating whether a lower region of the bonding pad has been damaged, based on a first number of logic level transitions of the first test output signal and a second number of logic level transitions of the second test output signal.

### BRIEF DESCRIPTION OF THE DRAWINGS

Embodiments will be more clearly understood from the following detailed description taken in conjunction with the accompanying drawings, in which:

FIG. 1 is a block diagram illustrating a test system according to an embodiment;

FIG. 2 is a block diagram illustrating a memory device according to an embodiment;

FIG. 3 is a block diagram illustrating a memory device according to an embodiment;

FIG. 4 is a block diagram illustrating a memory device according to an embodiment;

FIG. 5 illustrates a test input signal and test output signals according to an embodiment;

FIG. 6 is a graph showing an operation of a damage detection circuit according to an embodiment;

FIG. 7 is a block diagram illustrating a memory device according to an embodiment;

FIG. 8 is a block diagram illustrating a memory device according to an embodiment;

FIG. 9 is a block diagram illustrating a time-to-digital conversion circuit according to an embodiment;

FIG. 10 is a graph showing an operation of a damage detection circuit according to an embodiment;

FIG. 11 is a cross-sectional view illustrating a memory device according to an embodiment;

FIG. 12 is a cross-sectional view illustrating a memory device according to an embodiment;

FIG. 13 is a cross-sectional view illustrating a memory device according to an embodiment;

FIG. 14 is a diagram for describing a memory device according to an embodiment; and

FIG. 15 is a block diagram illustrating an example in which a memory device according to embodiments is applied to a solid state drive (SSD) system.

### DETAILED DESCRIPTION

Hereinafter, example embodiments will be described in detail with reference to the accompanying drawings. When describing embodiments with reference to the accompanying drawings, the same or corresponding elements are denoted by the same reference numerals, and redundant descriptions thereof are omitted.

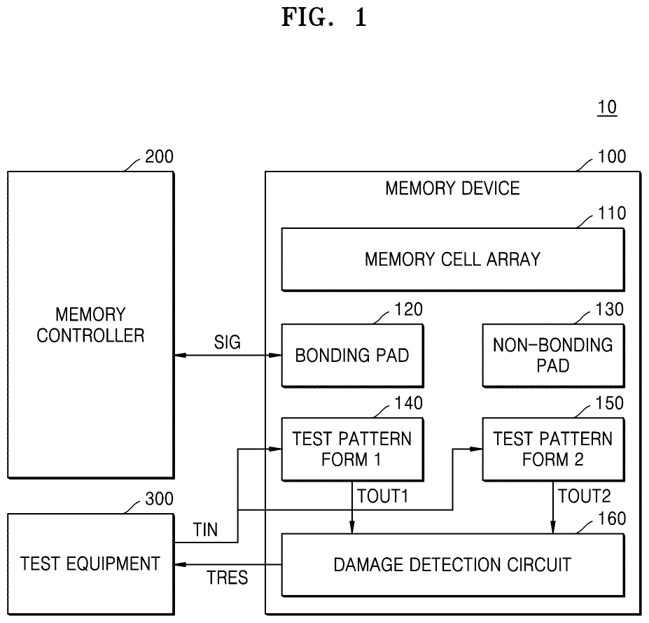

FIG. 1 is a block diagram illustrating a test system 10 according to an embodiment.

Referring to FIG. 1, the test system 10 may include a memory device 100, a memory controller 200, and test equipment 300.

The memory device 100 may include a memory cell array 110, a bonding pad 120, a non-bonding pad 130, a first test pattern form 140, a second test pattern form 150, and a damage detection circuit 160.

In an embodiment, the memory device 100 may include a non-volatile memory device, such as flash memory. In some embodiments, the memory device 100 may be embedded in an electronic device or may be detachably attached thereto. For example, the memory device 100 may be implemented in various forms, such as an embedded universal flash storage (UFS) memory, an embedded multi-media card (eMMC), a solid state drive (SSD), a UFS memory card, a compact flash (CF) memory, a secure digital (SD) memory, a micro-SD memory, a mini-SD memory, an extreme digital (xD) memory, or a memory stick.

In an embodiment, the memory device 100 may have a cell-over-periphery (COP) structure. For example, the memory device 100 may include a first semiconductor layer and a second semiconductor layer. The first semiconductor layer may include the memory cell array 110 and the second semiconductor layer may include peripheral circuits. The second semiconductor layer may be disposed below the first semiconductor layer in a vertical direction, and accordingly, the second semiconductor layer may be disposed close to a substrate.

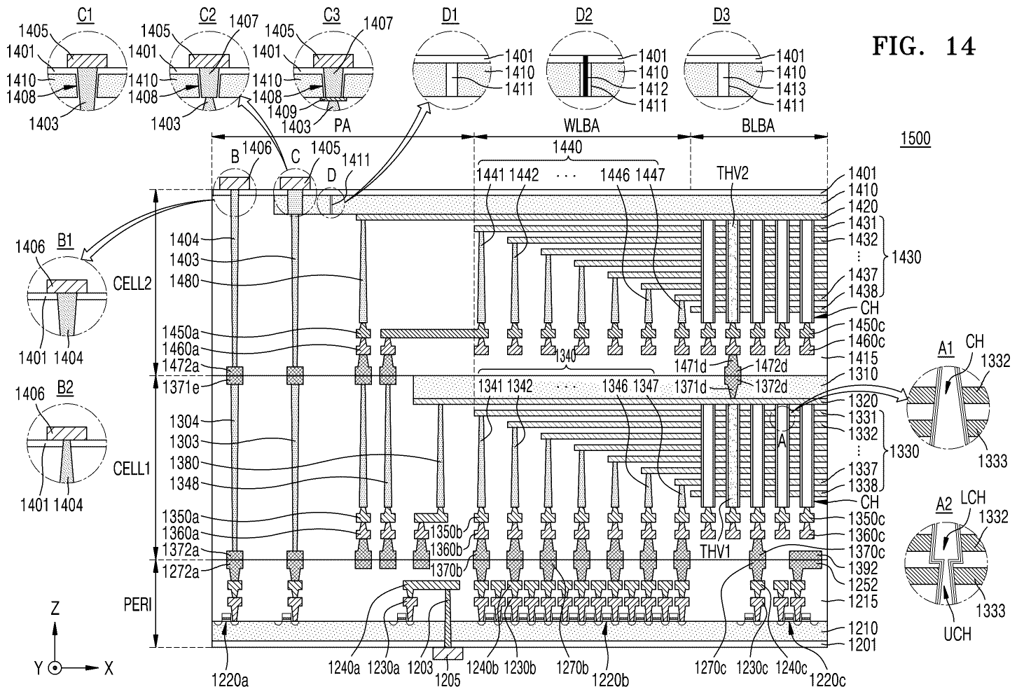

In an embodiment, the memory device 100 may have a chip-to-chip (C2C) structure. The C2C structure may refer to a structure formed by manufacturing at least one upper chip including a cell region (e.g., the memory cell array 110) and a lower chip including a peripheral circuit region and then bonding the at least one upper chip and the lower chip to each other. The C2C structure is described in detail below with reference to FIG. 14.

The memory cell array 110 may include a plurality of memory cells. For example, each of the memory cells may be a flash memory cell. Hereinafter, embodiments are described in detail on the assumption that each of the memory cells is a NAND flash memory cell. However, embodiments of the disclosure are not limited thereto, and in some embodiments, the memory cells may be resistive memory cells, such as resistive random access memory (RAM) (RRAM), phase change RAM (PRAM), ferroelectric RAM (FRAM), or magnetic RAM (MRAM).

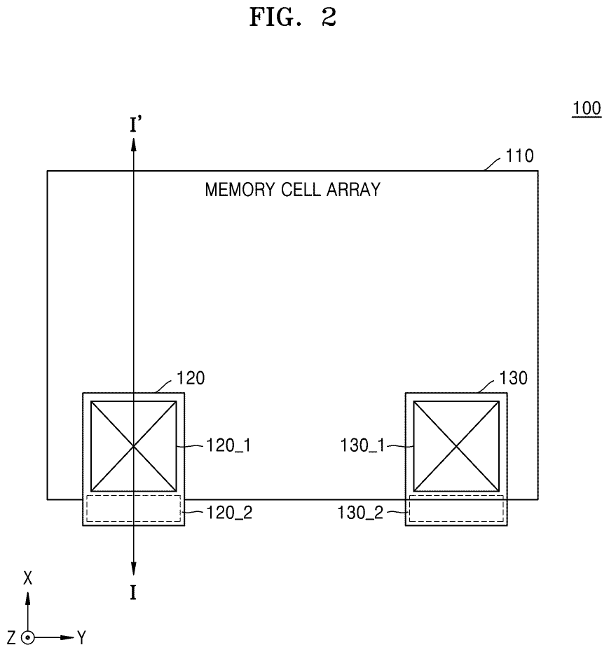

The bonding pad 120 may be a pad configured to electrically connect the memory device 100 to an external device. The bonding pad 120 may be disposed above the memory cell array 110 in a direction perpendicular to the memory cell array 110, and a detailed description thereof is given below with reference to FIG. 2.

In an embodiment, the external device may be, for example, the memory controller 200 illustrated in FIG. 1. The memory device 100 may communicate with the memory controller 200 by exchanging a signal SIG with the memory controller 200 through the bonding pad 120. The memory controller 200 may be wire-bonded to the memory device 100 through the bonding pad 120 and may communicate with the memory device 100 by exchanging the signal SIG with the memory device 100. The signal SIG that is exchanged between the memory device 100 and the memory controller 200 may include a command signal, an address signal, a data signal, and the like.

In addition, for example, the external device that is electrically connected to the memory device 100 may be the test equipment 300. In the present specification, the test equipment 300 may refer to automated test equipment (ATE) that tests the memory device 100. A probe of the test equipment 300 may come into contact with the bonding pad 120, and the test equipment 300 may test the memory device 100. At this time, the signal SIG the test equipment 300 provides to the memory device 100 through the bonding pad 120 may be different from a test input signal TIN that is provided to the memory device 100 through the first test pattern form 140 and the second test pattern form 150.

Although FIG. 1 illustrates that the memory device 100 includes only one bonding pad 120, this is only an example and the memory device 100 may include two or more bonding pads.

The non-bonding pad 130 may be a pad that is not electrically connected to the external device. The non-bonding pad 130 may be a pad used as a criterion for determining whether the lower region of the bonding pad 120 has been damaged. The non-bonding pad 130 may be disposed above the memory cell array 110 in a direction perpendicular to the memory cell array 110. A detailed description thereof is given below with reference to FIG. 2.

In an embodiment, external force may be applied to the bonding pad 120 of the memory device 100 in a process of electrically connecting the bonding pad 120 to the external device through wire bonding, or bring the probe of the test equipment 300 into contact with the bonding pad 120. Due to the external force, the lower region of the bonding pad 120 may be damaged. However, since the non-bonding pad 130 is not electrically connected to the external device, the lower region of the non-bonding pad 130 may not be damaged. When the lower region of the bonding pad 120 is damaged, the signal output from the first test pattern form 140 may be different from the signal output from the second test pattern form 150. Therefore, the signal output from the second test pattern form 150 disposed below the non-bonding pad 130 may be a reference value for determining whether the lower region of the bonding pad 120 has been damaged.

Although FIG. 1 illustrates that the memory device 100 includes only one non-bonding pad 130, this is only an example and the memory device 100 may include two or more non-bonding pads.

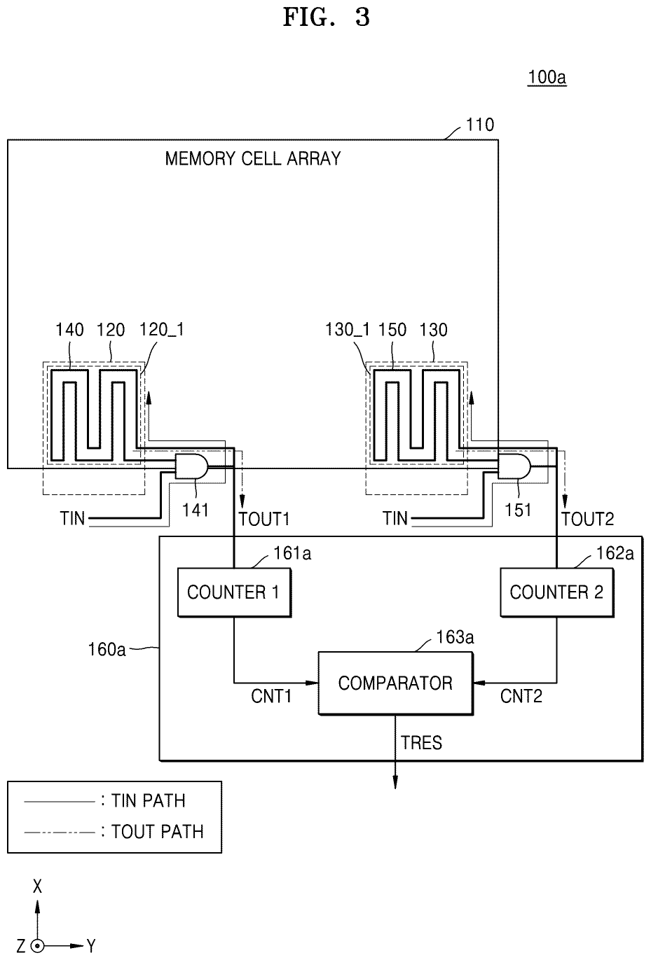

The first test pattern form 140 may receive a test input signal TIN from the test equipment 300. The first test pattern form 140 may output a first test output signal TOUT1 in response to the test input signal TIN. The first test pattern form 140 may be disposed below the bonding pad 120 in a vertical direction. In an example, the bonding pad is disposed above the memory cell array region, and at least a portion of the bonding pad is configured to overlap at least a portion of the memory cell array region in the vertical direction. A detailed description thereof is given below with reference to FIG. 3.

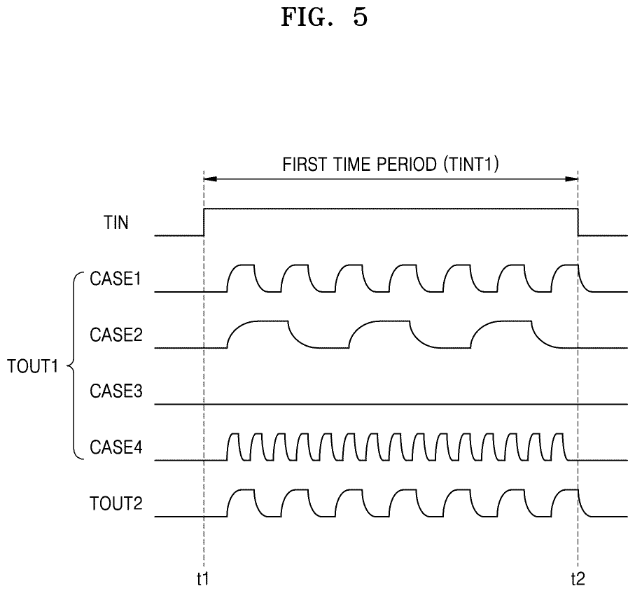

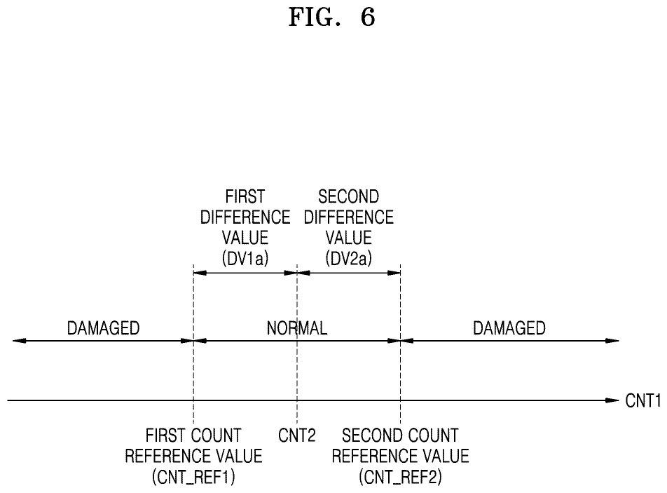

The first test output signal TOUT1 may be different from a second test output signal TOUT2 according to whether the lower region of the bonding pad 120 has been damaged. A detailed description thereof is given below with reference to FIGS. 5 and 6.

The second test pattern form 150 may receive the test input signal TIN from the test equipment 300. The second test pattern form 150 may output the second test output signal TOUT2 in response to the test input signal TIN. The second test pattern form 150 may be disposed below the non-bonding pad 130 in a vertical direction. In an example, at least a portion of the non-bonding pad is configured to overlap at least a portion of the memory cell array region in the vertical direction. A detailed description thereof is given below with reference to FIG. 3.

In an embodiment, the test input signal TIN applied to the first test pattern form 140 may be identical to the test input signal TIN applied to the second test pattern form 150.

In an embodiment, each of the first test pattern form 140 and the second test pattern form 150 may be formed of at least one of various conductive materials. For example, each of the first test pattern form 140 and the second test pattern form 150 may be formed of tungsten, copper, aluminum, or the like.

The damage detection circuit 160 may receive the first test output signal TOUT1 from the first test pattern form 140 and the second test output signal TOUT2 from the second test pattern form 150. The damage detection circuit 160 may generate a test result signal TRES based on the result of comparing the first test output signal TOUT1 with the second test output signal TOUT2. The test result signal TRES may include a value indicating whether the lower region of the bonding pad 120 has been damaged. For example, when the lower region of the bonding pad 120 has not been damaged, the test result signal TRES may include a first value indicating that the lower region of the bonding pad 120 is normal. Alternatively, when the lower region of the bonding pad 120 has been damaged, the test result signal TRES may include a second value indicating that the lower region of the bonding pad 120 has been damaged. The damage detection circuit 160 may provide the test result signal TRES to the test equipment 300.

In an embodiment, the damage detection circuit 160 may include a counter. The damage detection circuit 160 may count the number of times the logic levels of the first test output signal TOUT1 and the second test output signal TOUT2 transition. For example, the damage detection circuit 160 may output the test result signal TRES indicating whether a lower region of the bonding pad has been damaged, based on a first number of logic level transitions of the first test output signal and a second number of logic level transitions of the second test output signal. The damage detection circuit may generate the test result signal TRES based on the result of comparing a count value corresponding to the first test output signal TOUT1 with a count value corresponding to the second test output signal TOUT2. A detailed description thereof is given below with reference to FIGS. 3 to 6.

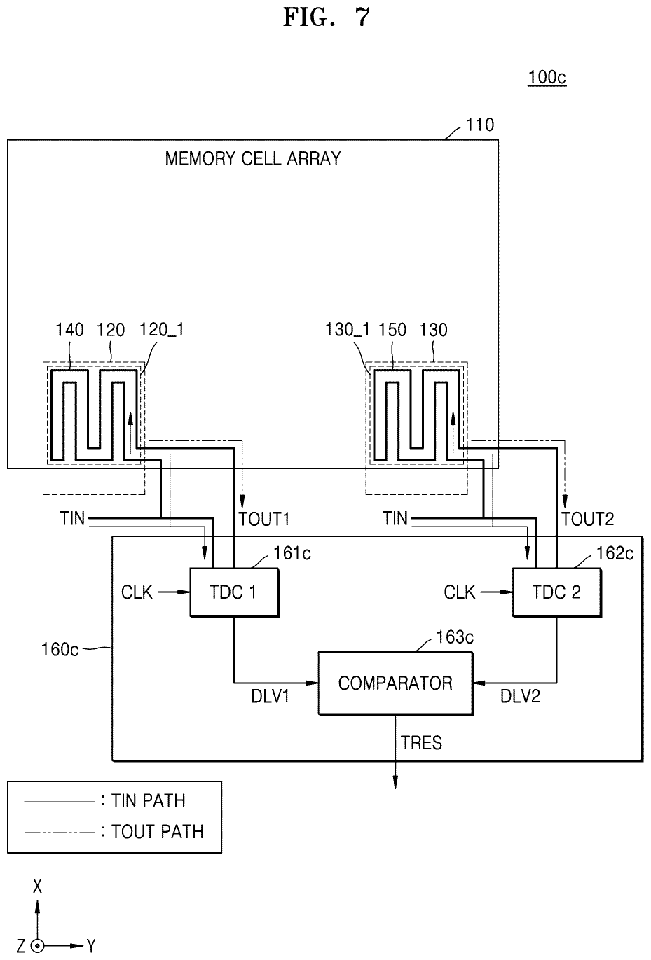

In an embodiment, the damage detection circuit 160 may include a time-to-digital conversion circuit. The damage detection circuit 160 may generate the test result signal TRES based on the result of comparing a delay time of the first test output signal TOUT1 with a delay time of the second test output signal TOUT2. A detailed description thereof is given below with reference to FIGS. 7 to 10. In an example, the damage detection circuit is configured to output a test result signal indicating whether a lower region of the bonding pad has been damaged, based on comparing the first delay time TOUT1 of the first test output signal with the second delay time TOUT2 of the second test output signal.

The memory device 100 according to an embodiment may determine whether the lower region of the bonding pad 120 has been damaged. In addition, the memory device 100 according to an embodiment may detect even fine damage to the lower region of the bonding pad 120 by comparing the first test output signal TOUT1 output from the first test pattern form 140 disposed in the lower region of the bonding pad 120 with the second test output signal TOUT2 output from the second test pattern form 150 disposed in the lower region of the non-bonding pad 130.

FIG. 2 is a block diagram illustrating the memory device 100 according to an embodiment. FIG. 2 may be described with reference to FIG. 1, and redundant descriptions may be omitted.

FIG. 2 illustrates a plan view of the memory device 100 in a vertical direction. In the present specification, unless specifically defined herein, the vertical direction may be referred to as a first direction or a Z direction. In addition, a direction perpendicular to the first direction may be referred to as a second direction or a Y direction. In addition, a direction perpendicular to the first direction and the second direction may be referred to as a third direction or an X direction. For convenience of understanding, those described as top/bottom surfaces, upper/lower portions, above/below, etc. are denoted based on the directions illustrated in the reference drawings. Accordingly, even the same surface may be referred to as a top surface and a bottom surface according to the directions illustrated in the drawings.

Referring to FIG. 2, the bonding pad 120 and the non-bonding pad 130 may be disposed above the memory cell array 110 in the vertical direction.

The lower region of the bonding pad 120 may be divided into a first region 120_1 and a second region 120_2. In the present specification, the first region 120_1 may refer to a region where the memory cell array 110 and the bonding pad 120 overlap each other in the vertical direction. In some embodiments, the first region 120_1 may be referred to as a cell region, a memory cell region, or a memory cell array region. The second region 120_2 may refer to a region where the memory cell array 110 and the bonding pad 120 do not overlap each other in the vertical direction. In some embodiments, the second region 120_2 may be referred to as a connection region.

The memory device 100 may detect damage to the first region 120_1 through the first test output signal TOUT1 output from the first test pattern form 140, which is a metal pattern disposed in the first region 120_1 at the lower portion of the bonding pad 120. A specific embodiment of detecting damage to the first region 120_1 is described below with reference to FIG. 3.

The second region 120_2 may refer to a region including a plurality of contacts for providing an electrical connection between the bonding pad 120 and the peripheral circuit included in the memory device 100.

At least a portion of the bonding pad 120 may overlap at least a portion of the memory cell array 110 in the first direction Z. The remaining portion of the bonding pad 120 may not overlap the memory cell array 110 in the first direction Z. For example, the first region 120_1 below the bonding pad 120 may overlap the memory cell array 110 in the first direction Z. In addition, for example, the second region 120_2 below the bonding pad 120 may not overlap the memory cell array 110 in the first direction Z.

The lower region of the non-bonding pad 130 may be divided into a memory cell region 130_1 and a connection region 130_2.

The memory device 100 may generate the test result signal TRES by comparing the second test output signal TOUT2 output from the second test pattern form 150, which is the metal pattern disposed in the memory cell region 130_1 of the non-bonding pad 130, with the first test output signal TOUT1, and the test result signal TRES may be used as a reference value for determining whether the first region 120_1 of the bonding pad 120 has been damaged.

The connection region 130_2 may refer to a region including a plurality of contacts for providing an electrical connection between the non-bonding pad 130 and the peripheral circuit included in the memory device 100.

At least a portion of the non-bonding pad 130 may overlap at least a portion of the memory cell array 110 in the first direction Z. The remaining portion of the non-bonding pad 130 may not overlap the memory cell array 110 in the first direction Z. For example, the memory cell region 130_1 below the non-bonding pad 130 may overlap the memory cell array 110 in the first direction Z. In addition, for example, the connection region 130_2 below the non-bonding pad 130 may not overlap the memory cell array 110 in the first direction Z.

The non-bonding pad 130 may be apart from the bonding pad 120 in the second direction.

FIG. 3 is a block diagram illustrating a memory device 100a according to an embodiment. FIG. 3 may be described with reference to FIGS. 1 and 2, and redundant descriptions may be omitted.

The memory device 100a of FIG. 3 may correspond to the memory device 100 of FIG. 1. Specifically, FIG. 3 may be a plan view of the first test pattern form 140 disposed below the bonding pad 120 and the second test pattern form 150 disposed below the non-bonding pad 130 in FIG. 2.

Referring to FIG. 3, the memory device 100a may include a memory cell array 110, a bonding pad 120, a non-bonding pad 130, a first test pattern form 140, a first NAND gate 141, a second test pattern form 150, a second NAND gate 151, and a damage detection circuit 160a.

The first test pattern form 140 may be disposed below the bonding pad 120. Specifically, the first test pattern form 140 may be disposed in a first region 120_1 in a lower region of the bonding pad 120.

The test equipment 300 may provide a test input signal TIN to the first test pattern form 140 through the first NAND gate 141. The test input signal TIN may pass through the first test pattern form 140 and may then be output through the first NAND gate 141 as a first test output signal TOUT1. That is, the first test pattern form 140 may provide the first test output signal TOUT1 to the damage detection circuit 160a.

The second test pattern form 150 may be disposed below the non-bonding pad 130. Specifically, the second test pattern form 150 may be disposed in a memory cell region 130_1 in a lower region of the non-bonding pad 130.

The test equipment 300 may provide the test input signal TIN to the second test pattern form 150 through the second NAND gate 151. The test input signal TIN may pass through the second test pattern form 150 and may then be output through the second NAND gate 151 as a second test output signal TOUT2. That is, the second test pattern form 150 may provide the second test output signal TOUT2 to the damage detection circuit 160a. The second test output signal TOUT2 may be a comparison criterion when a comparator 163a performs a comparison operation with the first test output signal TOUT1.

The damage detection circuit 160a may include a first counter 161a, a second counter 162a, and the comparator 163a.

The first counter 161a may receive the first test output signal TOUT1 from the first test pattern form 140. The first counter 161a may output a first count value CNT1 generated by counting the number of times the logic level of the first test output signal TOUT1 transitions during a first time period. For example, the first counter 161a may output the first count value CNT1 corresponding to transitions of the first test output signal from a high level to a low level during a first reference time period. In some embodiments, the first count value CNT1 may be a value composed of N bits (where N is a natural number greater than or equal to 1).

For example, the first counter 161a may count the number of times the logic level of the first test output signal TOUT1 transitions from a high level to a low level during the first time period. In addition, for example, the first counter 161a may count the number of times the logic level of the first test output signal TOUT1 transitions from a low level to a high level during the first time period.

The number of times the logic level of the first test output signal TOUT1 transitions may vary depending on whether the first region 120_1, where the first test pattern form 140 is located, has been damaged. A detailed description thereof is given below with reference to FIG. 5.

The second counter 162a may receive the second test output signal TOUT2 from the second test pattern form 150. The second counter 162a may output a second count value CNT2 generated by counting the number of times the logic level of the second test output signal TOUT2 transitions during the first time period. In some embodiments, the second count value CNT2 may be a value composed of N bits (where N is a natural number greater than or equal to 2).

For example, the second counter 162a may count the number of times the logic level of the second test output signal TOUT2 transitions from a high level to a low level during the first time period. In addition, for example, the second counter 162a may count the number of times the logic level of the second test output signal TOUT2 transitions from a low level to a high level during the first time period.

The comparator 163a may receive the first count value CNT1 from the first counter 161a and the second count value CNT2 from the second counter 162a. The comparator 163a may output a test result signal TRES based on the result of comparing the first count value CNT1 with the second count value CNT2. Specifically, the comparator 163a may generate the test result signal TRES indicating whether the lower region of the bonding pad 120 has been damaged, based on the degree of the difference between the first count value CNT1 and the second count value CNT2. A detailed description thereof is given below with reference to FIG. 6.

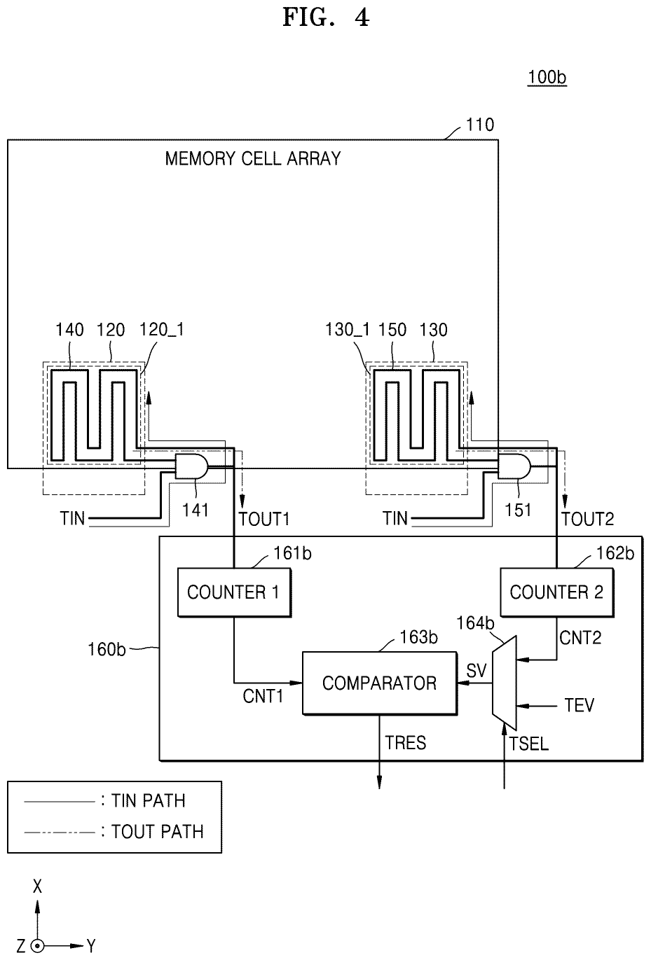

FIG. 4 is a block diagram illustrating a memory device 100b according to an embodiment. Specifically, a damage detection circuit 160b of FIG. 4 may further include a multiplexer 164b, compared to the damage detection circuit 160a of FIG. 3. FIG. 4 may be described with reference to FIGS. 1 to 3, and redundant descriptions may be omitted. In FIG. 4, the differences from the memory device 100a of FIG. 3 are mainly described.

Referring to FIG. 4, the memory device 100b of FIG. 4 may correspond to the memory device 100 of FIG. 1 and the memory device 100a of FIG. 3. The memory device 100b may include a memory cell array 110, a bonding pad 120, a non-bonding pad 130, a first test pattern form 140, a first NAND gate 141, a second test pattern form 150, a second NAND gate 151, and a damage detection circuit 160b.

The damage detection circuit 160b may include a first counter 161b, a second counter 162b, a comparator 163b, and the multiplexer 164b. The first counter 161b may correspond to the first counter 161a of FIG. 3 and the second counter 162b may correspond to the second counter 162a of FIG. 3.

The multiplexer 164b may receive a second count value CNT2 from the second counter 162b. In addition, the multiplexer 164b may receive a test expectation value TEV from the outside. In some embodiments, the test expectation value TEV may be a value previously input to the memory device 100b or an external value input by the test equipment 300. The test expectation value TEV may be different from the second count value CNT2.

The multiplexer 164b may select one of the second count value CNT2 and the test expectation value TEV based on a selection signal TSEL. The multiplexer 164b may provide a selected value SV to the comparator 163b. In some embodiments, the selection signal TSEL may be an external value input by the test equipment 300.

The comparator 163b may receive the first count value CNT1 from the first counter 161b and the selected value SV from the multiplexer 164b.

The comparator 163b may output a test result signal TRES based on the result of comparing the first count value CNT1 with the selected value SV. Specifically, the comparator 163b may generate the test result signal TRES indicating whether the lower region of the bonding pad 120 has been damaged, based on the degree of the difference between the first count value CNT1 and the selected value SV. A detailed description thereof is given below with reference to FIG. 6.

FIG. 5 illustrates a test input signal TIN and test output signals TOUT1 and TOUT2 according to an embodiment. FIG. 5 may be described with reference to FIGS. 1 to 4, and redundant descriptions may be omitted.

Referring to FIG. 5, the test input signal TIN may be applied to the first test pattern form 140 and the second test pattern form 150 during a first time period TINT1 from a first time t1 to a second time t2.

The damage detection circuit 160a may detect damage to the lower region of the bonding pad 120 based on the number of times the logic level of the first test output signal TOUT1 transitions from a low level to a high level. At this time, the second test output signal TOUT2 may be a determination criterion when the damage detection circuit 160a performs a comparison operation with the first test output signal TOUT1. In FIG. 5, it is assumed that the number of times the logic level of the second test output signal TOUT2 transitions from a low level to a high level during the first time period TINT1 is 7. Accordingly, the second count value CNT2 output by the second counter 162a may be 7. This is only an example to help understanding and not intended to limit the embodiments of the disclosure.

In an embodiment, when the lower region (e.g., the first region 120_1) of the bonding pad 120 has not been damaged, the form of the first test output signal TOUT1 may be the same as a first case CASEL illustrated in FIG. 5. In this case, the first test output signal TOUT1 may be the same as the second test output signal TOUT2. As illustrated in FIG. 5, the first count value CNT1 corresponding to the first case CASEL may be 7. Since the first count value CNT1 coincides with the second count value CNT2, the damage detection circuit 160a may output the test result signal TRES including the first value indicating that the lower region of the bonding pad 120 has not been damaged.

FIG. 5 illustrates that the form of the first test output signal TOUT1 corresponding to the first case CASE1 is the same as the second test output signal TOUT2, but in some embodiments, even when the form of the first test output signal TOUT1 corresponding to the first case CASE1 is not completely the same as the second test output signal TOUT2, the damage detection circuit 160a may determine the lower region of the bonding pad 120 has not been damaged. For example, when the difference between the first count value CNT1 and the second count value CNT2 is within an allowable error range, the damage detection circuit 160a may output the test result signal TRES including the first value indicating that the lower region of the bonding pad 120 has not been damaged. In the present specification, the expression “the form of the first test output signal TOUT1 is the same as the first case CASE1” may mean that the difference between the first count value CNT1 and the second count value CNT2 is within an allowable error range. A detailed description thereof is given below with reference to FIG. 6.

In an embodiment, when the lower region (e.g., the first region 120_1) of the bonding pad 120 has been damaged, the form of the first test output signal TOUT1 may be the same as a second case CASE2 illustrated in FIG. 5. The expression “the form of the first test output signal TOUT1 is the same as the second case CASE2” may mean that the lower region of the bonding pad 120 has been damaged, and thus, the first test pattern form 140 became thinner. As illustrated in FIG. 5, the first count value CNT1 corresponding to the second case CASE2 may be 3. Since the first count value CNT1 does not coincide with the second count value CNT2, the damage detection circuit 160a may output the test result signal TRES including the second value indicating that the lower region of the bonding pad 120 has been damaged.

In the present specification, the expression “the form of the first test output signal TOUT1 is the same as the second case CASE2” may mean that the difference between the first count value CNT1 and the second count value CNT2 is out of an allowable error range. A detailed description thereof is given below with reference to FIG. 6.

In an embodiment, when the lower region (e.g., the first region 120_1) of the bonding pad 120 has been damaged, the form of the first test output signal TOUT1 may be the same as a third case CASE3 illustrated in FIG. 5. The expression “the form of the first test output signal TOUT1 is the same as the third case CASE3” may mean that the lower region of the bonding pad 120 has been damaged, and thus, the first test pattern form 140 has been opened. As illustrated in FIG. 5, the first count value CNT1 corresponding to the third case CASE3 may be 0. Since the first count value CNT1 does not coincide with the second count value CNT2, the damage detection circuit 160a may output the test result signal TRES including the second value indicating that the lower region of the bonding pad 120 has been damaged.

In the present specification, the expression “the form of the first test output signal TOUT1 is the same as the third case CASE3” may mean that the difference between the first count value CNT1 and the second count value CNT2 is out of an allowable error range. A detailed description thereof is given below with reference to FIG. 6.

In an embodiment, when the lower region (e.g., the first region 120_1) of the bonding pad 120 has been damaged, the form of the first test output signal TOUT1 may be the same as a fourth case CASE4 illustrated in FIG. 5. The expression “the form of the first test output signal TOUT1 is the same as the fourth case CASE4” may mean that the lower region of the bonding pad 120 has been damaged, and thus, the first test pattern form 140 has been shorted. As illustrated in FIG. 5, the first count value CNT1 corresponding to the fourth case CASE4 may be 15. Since the first count value CNT1 does not coincide with the second count value CNT2, the damage detection circuit 160a may output the test result signal TRES including the second value indicating that the lower region of the bonding pad 120 has been damaged.

In the present specification, the expression “the form of the first test output signal TOUT1 is the same as the fourth case CASE4” may mean that the difference between the first count value CNT1 and the second count value CNT2 is out of an allowable error range. A detailed description thereof is given below with reference to FIG. 6.

FIG. 6 is a graph showing the operation of the damage detection circuit 160a according to an embodiment. Specifically, FIG. 6 is a graph showing the operation in which the comparator 163a of FIG. 3 compares the first count value CNT1 with the second count value CNT2. FIG. 6 may be described with reference to FIGS. 1 to 5, and redundant descriptions may be omitted.

FIG. 6 illustrates a graph showing whether the first count value CNT1 is within a normal range or a damage range.

When the difference between the first count value CNT1 and the second count value CNT2 is within an allowable error range, the damage detection circuit 160a may output the test result signal TRES including the first value indicating that the lower region of the bonding pad 120 has not been damaged. In contrast, when the difference between the first count value CNT1 and the second count value CNT2 is out of an allowable error range, the damage detection circuit 160a may output the test result signal TRES including the second value indicating that the lower region of the bonding pad 120 has been damaged.

Referring to FIG. 6, a first count reference value CNT_REF1 and a second count reference value CNT_REF2 may be defined based on the second count value CNT2. The first count reference value CNT_REF1 may be less than the second count value CNT2. The second count reference value CNT_REF2 may be greater than the second count value CNT2. The difference between the second count value CNT2 and the first count reference value CNT_REF1 may be referred to as a first difference value DV1a. The difference between the second count reference value CNT_REF2 and the second count value CNT2 may be referred to as a second difference value DV2a.

In an embodiment, the first difference value DV1a may be equal to or different from the second difference value DV2a. The first difference value DV1a and the second difference value DV2a may be determined by a value previously input to the memory device 100 or the test equipment 300 or a value input by a user.

When the first count value CNT1 is greater than the first count reference value CNT_REF1 and less than the second count reference value CNT_REF2, the damage detection circuit 160a may determine that the first count value CNT1 is within an allowable error range. Therefore, in this case, it may be considered that the first count value CNT1 is within a normal range. This may mean that the lower region of the bonding pad 120 has not been damaged. Therefore, when the first count value CNT1 is greater than the first count reference value CNT_REF1 and less than the second count reference value CNT_REF2, the damage detection circuit 160a may output the test result signal TRES including the first value.

When the first count value CNT1 is less than the first count reference value CNT_REF1 or greater than the second count reference value CNT_REF2, the damage detection circuit 160a may determine that the first count value CNT1 is out of an allowable error range. Therefore, in this case, it may be considered that the first count value CNT1 is within a damage range. This may mean that the lower region of the bonding pad 120 has been damaged. Therefore, when the first count value CNT1 is less than the first count reference value CNT_REF1 or greater than the second count reference value CNT_REF2, the damage detection circuit 160a may output the test result signal TRES including the second value. In an example, the damage detection circuit is configured to, based on the first count value CNT1 indicating the first number of logic level transitions of the first test output signal is less than the first count reference value CNT_REF1 or greater than the second count reference value CNT_REF2, output the test result signal TRES indicating that the lower region of the bonding pad has been damaged.

In an embodiment, even when the comparator 163b of FIG. 4 performs an operation of comparing the first count value CNT1 with the selected value SV, the comparator 163b of FIG. 4 may generate the test result signal TRES by performing an operation similar to that of the comparator 163a of FIG. 3.

FIG. 7 is a block diagram illustrating a memory device 100c according to an embodiment. FIG. 7 may be described with reference to FIGS. 1, 2, and 3, and redundant descriptions may be omitted.

Referring to FIG. 7, the memory device 100c of FIG. 7 may correspond to the memory device 100 of FIG. 1. Specifically, FIG. 7 may be a plan view of the first test pattern form 140 disposed below the bonding pad 120 and the second test pattern form 150 disposed below the non-bonding pad 130 in FIG. 2.

When compared to the memory device 100a of FIG. 3, the memory device 100c of FIG. 7 may be configured to include a first time-to-digital conversion circuit 161c instead of the first counter 161a and a second time-to-digital conversion circuit 162c instead of the second counter 162a.

Referring to FIG. 7, the memory device 100c may include a memory cell array 110, a bonding pad 120, a non-bonding pad 130, a first test pattern form 140, a second test pattern form 150, and a damage detection circuit 160c.

The first test pattern form 140 may be disposed below the bonding pad 120. Specifically, the first test pattern form 140 may be disposed in a first region 120_1 in a lower region of the bonding pad 120.

The test equipment 300 may provide a test input signal TIN to the first test pattern form 140 and the first time-to-digital conversion circuit 161c. The test input signal TIN may pass through the first test pattern form 140 and may then be output as a first test output signal TOUT1. That is, the first test pattern form 140 may provide the first test output signal TOUT1 to the damage detection circuit 160c.

The second test pattern form 150 may be disposed below the non-bonding pad 130. Specifically, the second test pattern form 150 may be disposed in a memory cell region 130_1 in a lower region of the non-bonding pad 130.

The test equipment 300 may provide the test input signal TIN to the second test pattern form 150 and the second time-to-digital conversion circuit 162c. The test input signal TIN may pass through the second test pattern form 150 and may be then output as a second test output signal TOUT2. That is, the second test pattern form 150 may provide the second test output signal TOUT2 to the damage detection circuit 160c. The second test output signal TOUT2 may be a comparison criterion when a comparator 163c performs a comparison operation with the first test output signal TOUT1.

The damage detection circuit 160c may include the first time-to-digital conversion circuit 161c, the second time-to-digital conversion circuit 162c, and the comparator 163c.

The first time-to-digital conversion circuit 161c may perform an operation based on a clock signal CLK. In some embodiments, the clock signal CLK may be generated by a peripheral circuit of the memory device 100c or may be generated by a clock generator separately provided in the damage detection circuit 160c.

The first time-to-digital conversion circuit 161c may receive the first test output signal TOUT1 and may output a first delay value DLV1 indicating the degree to which the first test output signal TOUT1 is delayed compared to the test input signal TIN. The first test output signal TOUT1 output by the first test pattern form 140 may be a signal delayed from the test input signal TIN by a first delay time. At this time, the first delay time may vary depending on whether the lower region of the bonding pad 120 has been damaged. The first delay value DLV1 may be a value corresponding to the first delay time. In some embodiments, the first delay value DLV1 may be a value composed of N bits (where N is a natural number greater than or equal to 1).

The second time-to-digital conversion circuit 162c may perform an operation based on the clock signal CLK. The second time-to-digital conversion circuit 162c may receive the second test output signal TOUT2 and may output a second delay value DLV2 indicating the degree to which the second test output signal TOUT2 is delayed compared to the test input signal TIN. The second test output signal TOUT2 output by the second test pattern form 150 may be a signal delayed from the test input signal TIN by a second delay time. The second delay value DLV2 may be a value corresponding to the second delay time. In some embodiments, the second delay value DLV2 may be a value composed of N bits (where N is a natural number greater than or equal to 2).

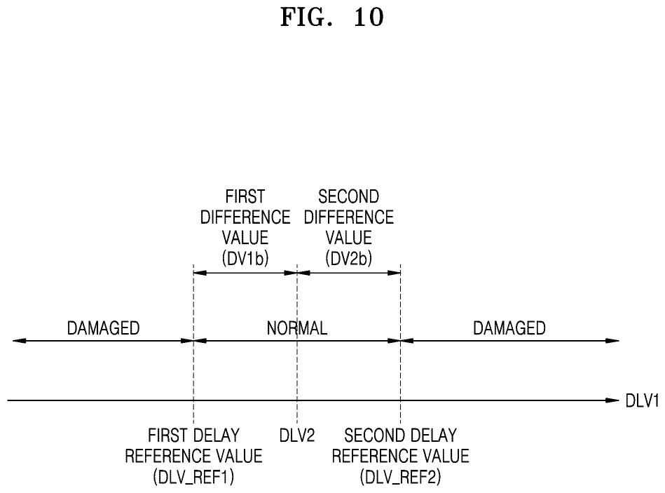

The comparator 163c may receive the first delay value DLV1 from the first time-to-digital conversion circuit 161c and may receive the second delay value DLV2 from the second time-to-digital conversion circuit 162c. The comparator 163c may output a test result signal TRES based on the result of comparing the first delay value DLV1 with the second delay value DLV2. Specifically, the comparator 163c may generate the test result signal TRES indicating whether the lower region of the bonding pad 120 has been damaged, based on the degree of the difference between the first delay value DLV1 and the second delay value DLV2. A detailed description thereof is given below with reference to FIG. 10.

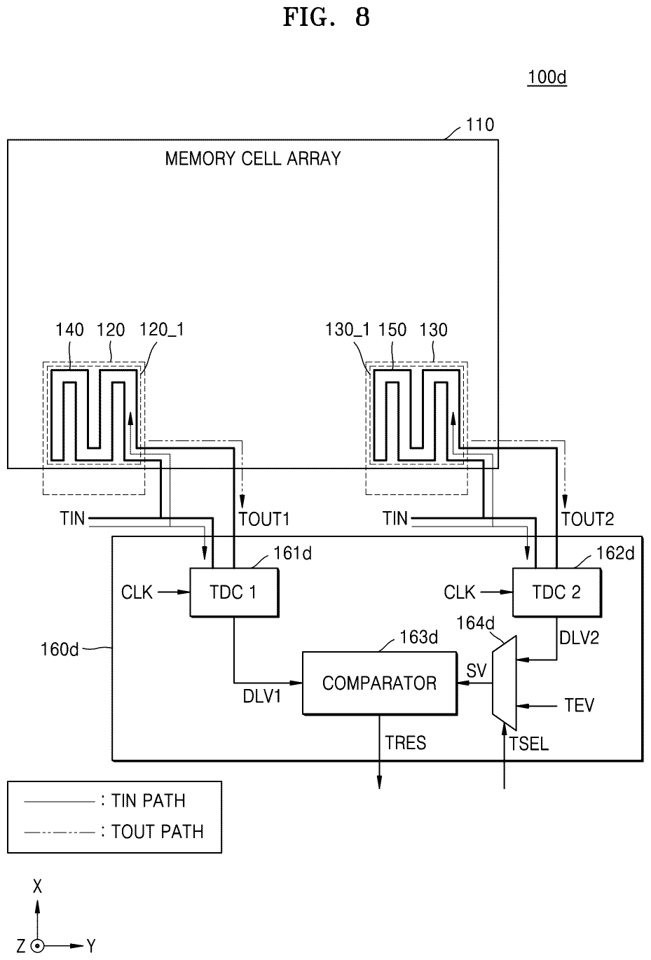

FIG. 8 is a block diagram illustrating a memory device 100d according to an embodiment. Specifically, a damage detection circuit 160d of FIG. 8 may further include a multiplexer 164d, compared to the damage detection circuit 160c of FIG. 7. FIG. 8 may be described with reference to FIGS. 1, 2, 4, and 7, and redundant descriptions may be omitted. In FIG. 8, the differences from the memory device 100c of FIG. 7 are mainly described.

Referring to FIG. 8, the memory device 100d of FIG. 8 may correspond to the memory device 100 of FIG. 1 and the memory device 100c of FIG. 7. The memory device 100d may include a memory cell array 110, a bonding pad 120, a non-bonding pad 130, a first test pattern form 140, a second test pattern form 150, and the damage detection circuit 160d.

The damage detection circuit 160d may include a first time-to-digital conversion circuit 161d, a second time-to-digital conversion circuit 162d, a comparator 163d, and the multiplexer 164d. The first time-to-digital conversion circuit 161d may correspond to the first time-to-digital conversion circuit 161c of FIG. 7 and the second time-to-digital conversion circuit 162d may correspond to the second time-to-digital conversion circuit 162c of FIG. 7.

The multiplexer 164d may receive a second delay value DLV2 from the second time-to-digital conversion circuit 162d. In addition, the multiplexer 164d may receive a test expectation value TEV from the outside. In some embodiments, the test expectation value TEV may be a value previously input to the memory device 100b or an external value input by the test equipment 300. The test expectation value TEV may be different from the second delay value DLV2.

The multiplexer 164d may select one of the second delay value DLV2 and the test expectation value TEV based on a selection signal TSEL. The multiplexer 164d may provide a selected value SV to the comparator 163d. In some embodiments, the selection signal TSEL may be an external value input by the test equipment 300.

The comparator 163d may receive a first delay value DLV1 from the first time-to-digital conversion circuit 161d and the selected value SV from the multiplexer 164d.

The comparator 163d may output a test result signal TRES based on the result of comparing the first delay value DLV1 with the selected value SV. Specifically, the comparator 163d may generate the test result signal TRES indicating whether the lower region of the bonding pad 120 has been damaged, based on the degree of the difference between the first delay value DLV1 and the selected value SV. A detailed description thereof is given below with reference to FIG. 10.

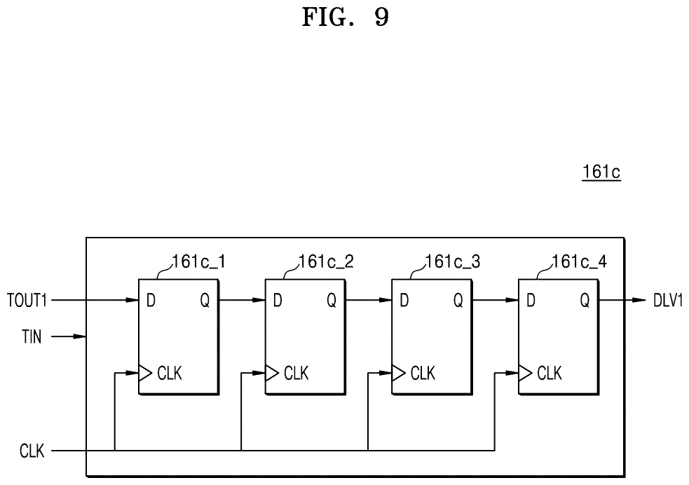

FIG. 9 is a block diagram illustrating a time-to-digital conversion circuit 161c according to an embodiment. Specifically, FIG. 9 is a diagram for describing the first time-to-digital conversion circuit 161c of FIG. 7. FIG. 9 may be described with reference to FIGS. 7 and 8, and redundant descriptions may be omitted.

Referring to FIG. 9, the first time-to-digital conversion circuit 161c may include a first flip-flop 161c_1, a second flip-flop 161c_2, a third flip-flop 161c_3, and a fourth flip-flop 161c_4. Although FIG. 9 illustrates that the first time-to-digital conversion circuit 161c includes four flip-flops, this is only an example to help understanding and not intended to limit the embodiments of the disclosure. Accordingly, the first time-to-digital conversion circuit 161c may include more or less than four flip-flops.

The first time-to-digital conversion circuit 161c may perform an operation based on a clock signal CLK. The first time-to-digital conversion circuit 161c may receive a first test output signal TOUT1, and the received first test output signal TOUT1 may be output as a first delay value DLV1 through the first flip-flop 161c_1 to the fourth flip-flop 161c_4. The first delay value DLV1 may be a value corresponding to a first delay time that is a delay time of the first test output signal TOUT1 with respect to a test input signal TIN.

Although FIG. 9 illustrates the first time-digital conversion circuit 161c of FIG. 7 as an example, the second time-to-digital conversion circuit 162c of FIG. 7 may be configured to have the same configuration as that of the first time-to-digital conversion circuit 161c of FIG. 9.

FIG. 10 is a graph showing the operation of the damage detection circuit 160c according to an embodiment. Specifically, FIG. 10 is a graph showing the operation in which the comparator 163c of FIG. 7 compares the first delay value DLV1 with the second delay value DLV2. FIG. 10 may be described with reference to FIGS. 1, 2, and 7 to 9, and redundant descriptions may be omitted.

FIG. 10 illustrates a graph showing whether the first delay value DLV1 is within a normal range or a damage range.

When the difference between the first delay value DLV1 and the second delay value DLV2 is within an allowable error range, the damage detection circuit 160c may output the test result signal TRES including the first value indicating that the lower region of the bonding pad 120 has not been damaged. In contrast, when the difference between the first delay value DLV1 and the second delay value DLV2 is out of an allowable error range, the damage detection circuit 160c may output the test result signal TRES including the second value indicating that the lower region of the bonding pad 120 has been damaged.

Referring to FIG. 10, a first delay reference value DLV_REF1 and a second delay reference value DLV_REF2 may be defined based on the second delay value DLV2. The first delay reference value DLV_REF1 may be less than the second delay value DLV2. The second delay reference value DLV_REF2 may be greater than the second delay value DLV2. The difference between the second delay value DLV2 and the first delay reference value DLV_REF1 may be referred to as a first difference value DV1a. The difference between the second delay reference value DLV_REF2 and the second delay value DLV2 may be referred to as a second difference value DV2a.

In an embodiment, the first difference value DV1a may be equal to or different from the second difference value DV2a. The first difference value DV1a and the second difference value DV2a may be determined by a value previously input to the memory device 100 or the test equipment 300 or a value input by a user.

When the first delay value DLV1 is greater than the first delay reference value DLV_REF1 and less than the second delay reference value DLV_REF2, the damage detection circuit 160c may determine that the first delay value DLV1 is within an allowable error range. Therefore, in this case, it may be considered that the first delay value DLV1 is within a normal range. This may mean that the lower region of the bonding pad 120 has not been damaged. Therefore, when the first delay value DLV1 is greater than the first delay reference value DLV_REF1 and less than the second delay reference value DLV_REF2, the damage detection circuit 160c may output the test result signal TRES including the first value.

When the first delay value DLV1 is less than the first delay reference value DLV_REF1 or greater than the second delay reference value DLV_REF2, the damage detection circuit 160c may determine that the first delay value DLV1 is out of an allowable error range. Therefore, in this case, it may be considered that the first delay value DLV1 is within a damage range. This may mean that the lower region of the bonding pad 120 has been damaged. Therefore, when the first delay value DLV1 is less than the first delay reference value DLV_REF1 or greater than the second delay reference value DLV_REF2, the damage detection circuit 160c may output the test result signal TRES including the second value.

In an embodiment, even when the comparator 163d of FIG. 8 performs an operation of comparing the first delay value DLV1 with the selected value SV, the comparator 163d of FIG. 8 may generate the test result signal TRES by performing an operation similar to that of the comparator 163c of FIG. 7.

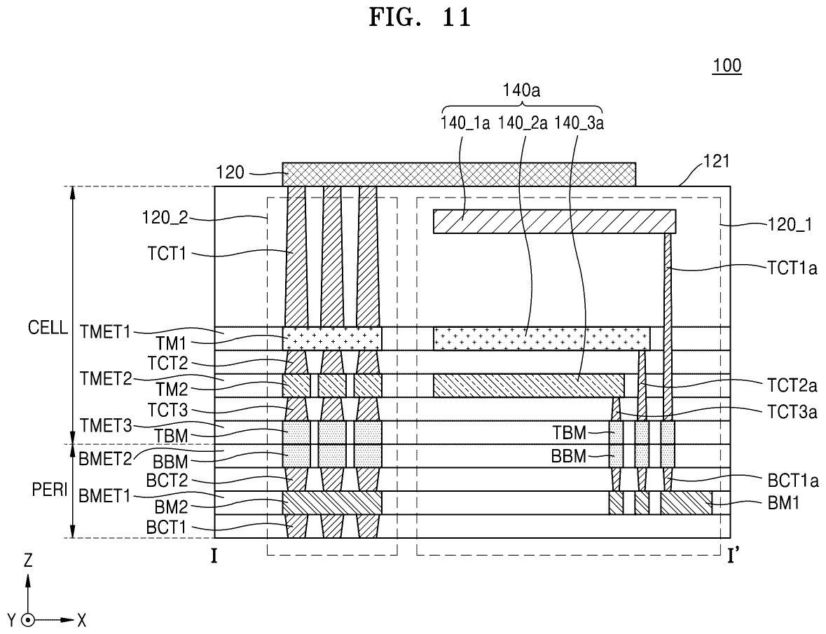

FIG. 11 is a cross-sectional view for describing a memory device 100 according to an embodiment. FIG. 11 may be described with reference to FIGS. 1 to 10, and redundant descriptions may be omitted.

FIG. 11 corresponds to a cross-section of the memory device 100 of FIG. 2 taken along line I-I′ of FIG. 2. FIG. 11 is a cross-sectional view of the bonding pad 120 and the lower region of the bonding pad 120. The cross-sectional view of the non-bonding pad 130 and the lower region of the non-bonding pad 130 may also be similar to FIG. 11.

Referring to FIG. 11, the memory device 100 may be divided into a cell region CELL and a peripheral circuit area PERI in a first direction and may be divided into a first region 120_1 and a second region 120_2 in a third direction.

The memory device 100 may include an insulating layer 121, a first upper metal layer TMET1, a second upper metal layer TMET2, a third upper metal layer TMET3, a first lower metal layer BMET1, and a second lower metal layer BMET2.

A first test pattern form 140a of FIG. 11 may correspond to the first test pattern form 140 of FIG. 1. The first test pattern form 140a may be disposed below the bonding pad 120. Specifically, the first test pattern form 140a may be disposed in a first region 120_1 in the lower region of the bonding pad 120. The first test pattern form 140a may include a first sub-test pattern form 140_1a, a second sub-test pattern form 140_2a, and a third sub-test pattern form 140_3a. The first test pattern form 140a including the three sub-test pattern forms is only an example to help understanding and not intended to limit embodiments of the disclosure. Accordingly, the first test pattern form 140a may include more or less than three sub-test pattern forms.

The bonding pad 120 may be connected to a first upper metal line TM1 through a first upper contact TCT1. The first upper metal layer TMET1 may include the first upper metal line TM1 and the second sub-test pattern form 140_2a. The first sub-test pattern form 140_1a may be disposed above the second sub-test pattern shape portion 140_2a in a vertical direction. The first sub-test pattern form 140_1a may be connected to an upper bonding metal pattern TBM through a first upper test pattern contact TCT1a. The second sub-test pattern form 140_2a may be connected to an upper bonding metal pattern TBM through a second upper test pattern contact TCT2a.

The second upper metal layer TMET2 may include a second upper metal line TM2 and the third sub-test pattern form 140_3a. The second upper metal line TM2 may be connected to the first upper metal line TM1 through a second upper contact TCT2. The third sub-test pattern form 140_3a may be disposed below the second sub-test pattern in an 140_2a in a vertical direction. The third sub-test pattern form 140_3a may be connected to an upper bonding metal pattern TBM through a third upper test pattern contact TCT3a.

The third upper metal layer TMET3 may include the upper bonding metal pattern TBM. The second lower metal layer BMET2 may include a lower bonding metal pattern BBM. The upper bonding metal pattern TBM of the third upper metal layer TMET3 and the lower bonding metal pattern BBM of the second lower metal layer BMET2 may be connected to each other by a bonding method.

The first lower metal layer BMET1 may include a first lower metal line BM1 disposed in the first region 120_1 and a second lower metal line BM2 disposed in the second region 120_2. The first lower metal line BM1 may be connected to the lower bonding metal pattern BBM through a first lower test pattern contact BCT1a. The second lower metal line BM2 may be connected to the lower bonding metal pattern BBM through a second lower contact BCT2. The second lower metal line BM2 may be connected to peripheral circuits of the memory device 100 through a first lower contact BCT1.

In an embodiment, when the first test pattern form 140a is configured as illustrated in FIG. 11, the test equipment 300 may apply the test input signal TIN to each of the first sub-test pattern form 140_1a, the second sub-test pattern form 140_2a, and the third sub-test pattern form 140_3a. In this case, the damage detection circuit 160 may determine which of the metal layers included in the memory device 100 damage has been damaged, through the test output signal received from each of the sub-test pattern forms. For example, the damage detection circuit 160 may determine whether a region, where the first sub-test pattern form 140_1a is disposed, has been damaged, through the test output signal received from the first sub-test pattern form 140_1a.

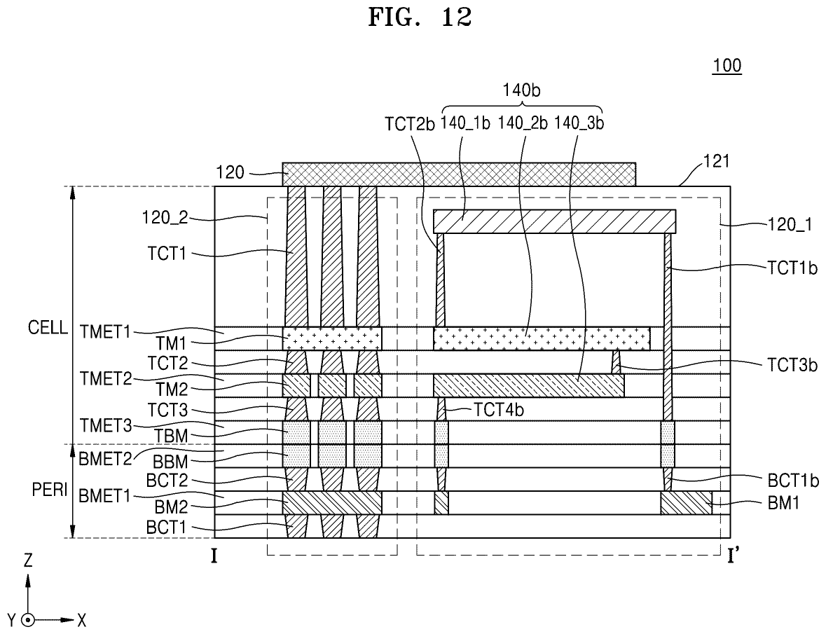

FIG. 12 is a cross-sectional view for describing a memory device 100 according to an embodiment. FIG. 12 may be described with reference to FIGS. 1 to 11, and redundant descriptions may be omitted. In FIG. 12, the differences from FIG. 11 are mainly described.

FIG. 12 corresponds to a cross-section of the memory device 100 of FIG. 2 taken along line I-I′ of FIG. 2. FIG. 12 is a cross-sectional view of the bonding pad 120 and the lower region of the bonding pad 120. The cross-sectional view of the non-bonding pad 130 and the lower region of the non-bonding pad 130 may also be similar to FIG. 12. A first test pattern form 140b of FIG. 12 may correspond to the first test pattern form 140 of FIG. 1.

Referring to FIG. 12, the first test pattern form 140b may include a first sub-test pattern form 140_1b, a second sub-test pattern form 140_2b, and a third sub-test pattern form 140_3b.

The first sub-test pattern form 140_1b may be connected to an upper bonding metal pattern TBM through a first upper test pattern contact TCT1b. The first sub-test pattern form 140_1b may be connected to the second sub-test pattern form 140_2b through a second upper test pattern contact TCT2b. The second sub-test pattern form 140_2b may be connected to the third sub-test pattern shape portion 140_3b through a third upper test pattern contact TCT3b. The third sub-test pattern form 140_3b may be connected to an upper bonding metal pattern TBM through a fourth upper test pattern contact TCT4b. The first lower metal line BM1 may be connected to the lower bonding metal pattern BBM through a first lower test pattern contact BCT1b.

In an embodiment, when the first test pattern form 140b is configured as illustrated in FIG. 12, the damage detection circuit 160 may determine that the lower region of the bonding pad 120 has been damaged, based on a test output signal provided from one of the first sub-test pattern form 140_1b, the second sub-test pattern form 140_2b, and the third sub-test pattern form 140_3b.

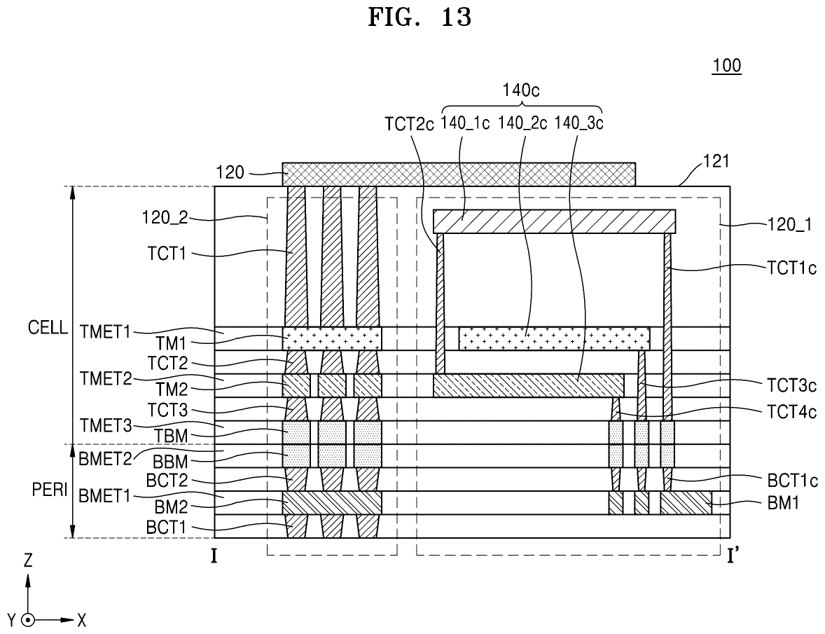

FIG. 13 is a cross-sectional view for describing a memory device 100 according to an embodiment. FIG. 13 may be described with reference to FIGS. 1 to 12, and redundant descriptions may be omitted. In FIG. 13, the differences from FIG. 11 are mainly described.

FIG. 13 corresponds to a cross-section of the memory device 100 of FIG. 2 taken along line I-I′ of FIG. 2. FIG. 13 is a cross-sectional view of the bonding pad 120 and the lower region of the bonding pad 120. The cross-sectional view of the non-bonding pad 130 and the lower region of the non-bonding pad 130 may also be similar to FIG. 13. A first test pattern form 140c of FIG. 13 may correspond to the first test pattern form 140 of FIG. 1.

Referring to FIG. 13, the first test pattern form 140c may include a first sub-test pattern form 140_1c, a second sub-test pattern form 140_2c, and a third sub-test pattern form 140_3c.

The first sub-test pattern form 140_1c may be connected to an upper bonding metal pattern TBM through a first upper test pattern contact TCT1c. The first sub-test pattern form 140_1c may be connected to the third sub-test pattern form 140_3c through a second upper test pattern contact TCT2c. The second sub-test pattern form 140_2c may be connected to an upper bonding metal pattern TBM through a third upper test pattern contact TCT3c. The third sub-test pattern form 140_3c may be connected to an upper bonding metal pattern TBM through a fourth upper test pattern contact TCT4c. The first lower metal line BM1 may be connected to the lower bonding metal pattern BBM through a first lower test pattern contact BCT1c.

In an embodiment, when the first test pattern form 140c is configured as illustrated in FIG. 13, the damage detection circuit 160 may detect a bridge between the sub-test pattern forms. In other words, the damage detection circuit 160 may detect damage occurring between the sub-test pattern forms. For example, the first sub-test pattern form 140_1c may not be connected to the second sub-test pattern form 140_2c and may be connected to the third sub-test pattern form 140_3c. At this time, when a bridge exists between the first sub-test pattern form 140_1c and the second sub-test pattern form 140_2c, a signal applied from the second sub-test pattern form 140_2c to the first sub-test pattern form 140_1c may be detected. In this manner, the damage detection circuit 160 may detect a bridge occurring between the first sub-test pattern form 140_1c and the second sub-test pattern form 140_2c. This may mean that the lower region the bonding pad 120 has been damaged.

FIG. 14 is a view illustrating a memory device 1500 according to some embodiments.

Referring to FIG. 14, the memory device 1500 may have a C2C structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 1500 may include the at least one upper chip including the cell region. For example, as illustrated in FIG. 14, the memory device 1500 may include two upper chips. However, the number of the upper chips is not limited thereto. In the case in which the memory device 1500 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 1500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 14. However, embodiments are not limited thereto. In certain embodiments, one of the first upper chip and the second upper chip may be turned over and then may be connected to a corresponding chip by the bonding method.

Each of the peripheral circuit region PERI and the first and second cell regions CELL1 and CELL2 of the memory device 1500 may include an external pad bonding region PA, a word line bonding region WLBA, and a bit line bonding region BLBA.

The peripheral circuit region PERI may include a first substrate 1210 and a plurality of circuit elements 1220a, 1220b and 1220c formed on the first substrate 1210. An interlayer insulating layer 1215 including one or more insulating layers may be provided on the plurality of circuit elements 1220a, 1220b and 1220c, and a plurality of metal lines electrically connected to the plurality of circuit elements 1220a, 1220b and 1220c may be provided in the interlayer insulating layer 1215. For example, the plurality of metal lines may include first metal lines 1230a, 1230b and 1230c connected to the plurality of circuit elements 1220a, 1220b and 1220c, and second metal lines 1240a, 1240b and 1240c formed on the first metal lines 1230a, 1230b and 1230c. The plurality of metal lines may be formed of at least one of various conductive materials. For example, the first metal lines 1230a, 1230b and 1230c may be formed of tungsten having a relatively high electrical resistivity, and the second metal lines 1240a, 1240b and 1240c may be formed of copper having a relatively low electrical resistivity.

The first metal lines 1230a, 1230b and 1230c and the second metal lines 1240a, 1240b and 1240c are illustrated and described in the present embodiments. However, embodiments are not limited thereto. In certain embodiments, at least one or more additional metal lines may further be formed on the second metal lines 1240a, 1240b and 1240c. In this case, the second metal lines 1240a, 1240b and 1240c may be formed of aluminum, and at least some of the additional metal lines formed on the second metal lines 1240a, 1240b and 1240c may be formed of copper having an electrical resistivity lower than that of aluminum of the second metal lines 1240a, 1240b and 1240c.

The interlayer insulating layer 1215 may be disposed on the first substrate 1210 and may include an insulating material such as silicon oxide and/or silicon nitride.

Each of the first and second cell regions CELL1 and CELL2 may include at least one memory block. The first cell region CELL1 may include a second substrate 1310 and a common source line 1320. A plurality of word lines 1330 (1331 to 1338) may be stacked on the second substrate 1310 in a direction (i.e., the Z-axis direction) perpendicular to a top surface of the second substrate 1310. String selection lines and a ground selection line may be disposed on and under the word lines 1330, and the plurality of word lines 1330 may be disposed between the string selection lines and the ground selection line. Likewise, the second cell region CELL2 may include a third substrate 1410 and a common source line 1420, and a plurality of word lines 1430 (1431 to 1438) may be stacked on the third substrate 1410 in a direction (i.e., the Z-axis direction) perpendicular to a top surface of the third substrate 1410. Each of the second substrate 1310 and the third substrate 1410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some embodiments, as illustrated in a region ‘A1’, the channel structure CH may be provided in the bit line bonding region BLBA and may extend in the direction perpendicular to the top surface of the second substrate 1310 to penetrate the word lines 1330, the string selection lines, and the ground selection line. The channel structure CH may include a data storage layer, a channel layer, and a filling insulation layer. The channel layer may be electrically connected to a first metal line 1350c and a second metal line 1360c in the bit line bonding region BLBA. For example, the second metal line 1360c may be a bit line and may be connected to the channel structure CH through the first metal line 1350c. The bit line 1360c may extend in a first direction (e.g., a Y-axis direction) parallel to the top surface of the second substrate 1310.

In some embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 1310 to penetrate the common source line 1320 and lower word lines 1331 and 1332. The lower channel LCH may include a data storage layer, a channel layer, and a filling insulation layer and may be connected to the upper channel UCH. The upper channel UCH may penetrate upper word lines 1333 to 1338. The upper channel UCH may include a data storage layer, a channel layer, and a filling insulation layer, and the channel layer of the upper channel UCH may be electrically connected to the first metal line 1350c and the second metal line 1360c. As a length of a channel increases, due to characteristics of manufacturing processes, it may be difficult to form a channel having a substantially uniform width. The memory device 1500 according to the present embodiments may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a word line located near to a boundary between the lower channel LCH and the upper channel UCH may be a dummy word line. For example, the word lines 1332 and 1333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

Meanwhile, the number of the lower word lines 1331 and 1332 penetrated by the lower channel LCH is less than the number of the upper word lines 1333 to 1338 penetrated by the upper channel UCH in the region ‘A2’. However, embodiments are not limited thereto. In certain embodiments, the number of the lower word lines penetrated by the lower channel LCH may be equal to or more than the number of the upper word lines penetrated by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 14, the first through-electrode THV1 may penetrate the common source line 1320 and the plurality of word lines 1330. In certain embodiments, the first through-electrode THV1 may further penetrate the second substrate 1310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected to each other through a first through-metal pattern 1372d and a second through-metal pattern 1472d. The first through-metal pattern 1372d may be formed at a bottom end of the first upper chip including the first cell region CELL1, and the second through-metal pattern 1472d may be formed at a top end of the second upper chip including the second cell region CELL2. The first through-electrode THV1 may be electrically connected to the first metal line 1350c and the second metal line 1360c. A lower via 1371d may be formed between the first through-electrode THV1 and the first through-metal pattern 1372d, and an upper via 1471d may be formed between the second through-electrode THV2 and the second through-metal pattern 1472d. The first through-metal pattern 1372d and the second through-metal pattern 1472d may be connected to each other by the bonding method.

In addition, in the bit line bonding region BLBA, an upper metal pattern 1252 may be formed in an uppermost metal layer of the peripheral circuit region PERI, and an upper metal pattern 1392 having the same shape as the upper metal pattern 1252 may be formed in an uppermost metal layer of the first cell region CELL1. The upper metal pattern 1392 of the first cell region CELL1 and the upper metal pattern 1252 of the peripheral circuit region PERI may be electrically connected to each other by the bonding method. In the bit line bonding region BLBA, the bit line 1360c may be electrically connected to a page buffer included in the peripheral circuit region PERI. For example, some of the circuit elements 1220c of the peripheral circuit region PERI may constitute the page buffer, and the bit line 1360c may be electrically connected to the circuit elements 1220c constituting the page buffer through an upper bonding metal pattern 1370c of the first cell region CELL1 and an upper bonding metal pattern 1270c of the peripheral circuit region PERI.

Referring continuously to FIG. 14, in the word line bonding region WLBA, the word lines 1330 of the first cell region CELL1 may extend in a second direction (e.g., an X-axis direction) parallel to the top surface of the second substrate 1310 and may be connected to a plurality of cell contact plugs 1340 (1341 to 1347). First metal lines 1350b and second metal lines 1360b may be sequentially connected onto the cell contact plugs 1340 connected to the word lines 1330. In the word line bonding region WLBA, the cell contact plugs 1340 may be connected to the peripheral circuit region PERI through upper bonding metal patterns 1370b of the first cell region CELL1 and upper bonding metal patterns 1270b of the peripheral circuit region PERI.

The cell contact plugs 1340 may be electrically connected to a row decoder included in the peripheral circuit region PERI. For example, some of the circuit elements 1220b of the peripheral circuit region PERI may constitute the row decoder, and the cell contact plugs 1340 may be electrically connected to the circuit elements 1220b constituting the row decoder through the upper bonding metal patterns 1370b of the first cell region CELL1 and the upper bonding metal patterns 1270b of the peripheral circuit region PERI. In some embodiments, an operating voltage of the circuit elements 1220b constituting the row decoder may be different from an operating voltage of the circuit elements 1220c constituting the page buffer. For example, the operating voltage of the circuit elements 1220c constituting the page buffer may be greater than the operating voltage of the circuit elements 1220b constituting the row decoder.

Likewise, in the word line bonding region WLBA, the word lines 1430 of the second cell region CELL2 may extend in the second direction (e.g., the X-axis direction) parallel to the top surface of the third substrate 1410 and may be connected to a plurality of cell contact plugs 1440 (1441 to 1447). The cell contact plugs 1440 may be connected to the peripheral circuit region PERI through an upper metal pattern of the second cell region CELL2 and lower and upper metal patterns and a cell contact plug 1348 of the first cell region CELL1.

In the word line bonding region WLBA, the upper bonding metal patterns 1370b may be formed in the first cell region CELL1, and the upper bonding metal patterns 1270b may be formed in the peripheral circuit region PERI. The upper bonding metal patterns 1370b of the first cell region CELL1 and the upper bonding metal patterns 1270b of the peripheral circuit region PERI may be electrically connected to each other by the bonding method. The upper bonding metal patterns 1370b and the upper bonding metal patterns 1270b may be formed of aluminum, copper, or tungsten.

In the external pad bonding region PA, a lower metal pattern 1371e may be formed in a lower portion of the first cell region CELL1, and an upper metal pattern 1472a may be formed in an upper portion of the second cell region CELL2. The lower metal pattern 1371e of the first cell region CELL1 and the upper metal pattern 1472a of the second cell region CELL2 may be connected to each other by the bonding method in the external pad bonding region PA. Likewise, an upper metal pattern 1372a may be formed in an upper portion of the first cell region CELL1, and an upper metal pattern 1272a may be formed in an upper portion of the peripheral circuit region PERI. The upper metal pattern 1372a of the first cell region CELL1 and the upper metal pattern 1272a of the peripheral circuit region PERI may be connected to each other by the bonding method.

Common source line contact plugs 1380 and 1480 may be disposed in the external pad bonding region PA. The common source line contact plugs 1380 and 1480 may be formed of a conductive material such as a metal, a metal compound, and/or doped polysilicon. The common source line contact plug 1380 of the first cell region CELL1 may be electrically connected to the common source line 1320, and the common source line contact plug 1480 of the second cell region CELL2 may be electrically connected to the common source line 1420. A first metal line 1350a and a second metal line 1360a may be sequentially stacked on the common source line contact plug 1380 of the first cell region CELL1, and a first metal line 1450a and a second metal line 1460a may be sequentially stacked on the common source line contact plug 1480 of the second cell region CELL2.

Input/output pads 1205, 1405 and 1406 may be disposed in the external pad bonding region PA. Referring to FIG. 14, a lower insulating layer 1201 may cover a bottom surface of the first substrate 1210, and a first input/output pad 1205 may be formed on the lower insulating layer 1201. The first input/output pad 1205 may be connected to at least one of a plurality of the circuit elements 1220a disposed in the peripheral circuit region PERI through a first input/output contact plug 1203 and may be separated from the first substrate 1210 by the lower insulating layer 1201. In addition, a side insulating layer may be disposed between the first input/output contact plug 1203 and the first substrate 1210 to electrically isolate the first input/output contact plug 1203 from the first substrate 1210.

An upper insulating layer 1401 covering a top surface of the third substrate 1410 may be formed on the third substrate 1410. A second input/output pad 1405 and/or a third input/output pad 1406 may be disposed on the upper insulating layer 1401. The second input/output pad 1405 may be connected to at least one of the plurality of circuit elements 1220a disposed in the peripheral circuit region PERI through second input/output contact plugs 1403 and 1303, and the third input/output pad 1406 may be connected to at least one of the plurality of circuit elements 1220a disposed in the peripheral circuit region PERI through third input/output contact plugs 1404 and 1304.

In some embodiments, the third substrate 1410 may not be disposed in a region in which the input/output contact plug is disposed. For example, as illustrated in a region ‘B’, the third input/output contact plug 1404 may be separated from the third substrate 1410 in a direction parallel to the top surface of the third substrate 1410 and may penetrate an interlayer insulating layer 1415 of the second cell region CELL2 so as to be connected to the third input/output pad 1406. In this case, the third input/output contact plug 1404 may be formed by at least one of various processes.

In some embodiments, as illustrated in a region ‘B1’, the third input/output contact plug 1404 may extend in a third direction (e.g., the Z-axis direction), and a diameter of the third input/output contact plug 1404 may become progressively greater toward the upper insulating layer 1401. In other words, a diameter of the channel structure CH described in the region ‘A1’ may become progressively less toward the upper insulating layer 1401, but the diameter of the third input/output contact plug 1404 may become progressively greater toward the upper insulating layer 1401. For example, the third input/output contact plug 1404 may be formed after the second cell region CELL2 and the first cell region CELL1 are bonded to each other by the bonding method.

In certain embodiments, as illustrated in a region ‘B2’, the third input/output contact plug 1404 may extend in the third direction (e.g., the Z-axis direction), and a diameter of the third input/output contact plug 1404 may become progressively less toward the upper insulating layer 1401. In other words, like the channel structure CH, the diameter of the third input/output contact plug 1404 may become progressively less toward the upper insulating layer 1401. For example, the third input/output contact plug 1404 may be formed together with the cell contact plugs 1440 before the second cell region CELL2 and the first cell region CELL1 are bonded to each other.

In certain embodiments, the input/output contact plug may overlap with the third substrate 1410. For example, as illustrated in a region ‘C’, the second input/output contact plug 1403 may penetrate the interlayer insulating layer 1415 of the second cell region CELL2 in the third direction (e.g., the Z-axis direction) and may be electrically connected to the second input/output pad 1405 through the third substrate 1410. In this case, a connection structure of the second input/output contact plug 1403 and the second input/output pad 1405 may be realized by various methods.

In some embodiments, as illustrated in a region ‘C1’, an opening 1408 may be formed to penetrate the third substrate 1410, and the second input/output contact plug 1403 may be connected directly to the second input/output pad 1405 through the opening 1408 formed in the third substrate 1410. In this case, as illustrated in the region ‘C1’, a diameter of the second input/output contact plug 1403 may become progressively greater toward the second input/output pad 1405. However, embodiments are not limited thereto, and in certain embodiments, the diameter of the second input/output contact plug 1403 may become progressively less toward the second input/output pad 1405.

In certain embodiments, as illustrated in a region ‘C2’, the opening 1408 penetrating the third substrate 1410 may be formed, and a contact 1407 may be formed in the opening 1408. An end of the contact 1407 may be connected to the second input/output pad 1405, and another end of the contact 1407 may be connected to the second input/output contact plug 1403. Thus, the second input/output contact plug 1403 may be electrically connected to the second input/output pad 1405 through the contact 1407 in the opening 1408. In this case, as illustrated in the region ‘C2’, a diameter of the contact 1407 may become progressively greater toward the second input/output pad 1405, and a diameter of the second input/output contact plug 1403 may become progressively less toward the second input/output pad 1405. For example, the second input/output contact plug 1403 may be formed together with the cell contact plugs 1440 before the second cell region CELL2 and the first cell region CELL1 are bonded to each other, and the contact 1407 may be formed after the second cell region CELL2 and the first cell region CELL1 are bonded to each other.

In certain embodiments illustrated in a region ‘C3’, a stopper 1409 may further be formed on a bottom end of the opening 1408 of the third substrate 1410, as compared with the embodiments of the region ‘C2’. The stopper 1409 may be a metal line formed in the same layer as the common source line 1420. Alternatively, the stopper 1409 may be a metal line formed in the same layer as at least one of the word lines 1430. The second input/output contact plug 1403 may be electrically connected to the second input/output pad 1405 through the contact 1407 and the stopper 1409.

Like the second and third input/output contact plugs 1403 and 1404 of the second cell region CELL2, a diameter of each of the second and third input/output contact plugs 1303 and 1304 of the first cell region CELL1 may become progressively less toward the lower metal pattern 1371e or may become progressively greater toward the lower metal pattern 1371e.

Meanwhile, in some embodiments, a slit 1411 may be formed in the third substrate 1410. For example, the slit 1411 may be formed at a certain position of the external pad bonding region PA. For example, as illustrated in a region ‘D’, the slit 1411 may be located between the second input/output pad 1405 and the cell contact plugs 1440 when viewed in a plan view. Alternatively, the second input/output pad 1405 may be located between the slit 1411 and the cell contact plugs 1440 when viewed in a plan view.

In some embodiments, as illustrated in a region ‘D1’, the slit 1411 may be formed to penetrate the third substrate 1410. For example, the slit 1411 may be used to prevent the third substrate 1410 from being finely cracked when the opening 1408 is formed. However, embodiments are not limited thereto, and in certain embodiments, the slit 1411 may be formed to have a depth ranging from about 60% to about 70% of a thickness of the third substrate 1410.

In certain embodiments, as illustrated in a region ‘D2’, a conductive material 1412 may be formed in the slit 1411. For example, the conductive material 1412 may be used to discharge a leakage current occurring in driving of the circuit elements in the external pad bonding region PA to the outside. In this case, the conductive material 1412 may be connected to an external ground line.

In certain embodiments, as illustrated in a region ‘D3’, an insulating material 1413 may be formed in the slit 1411. For example, the insulating material 1413 may be used to electrically isolate the second input/output pad 1405 and the second input/output contact plug 1403 disposed in the external pad bonding region PA from the word line bonding region WLBA. Since the insulating material 1413 is formed in the slit 1411, it is possible to prevent a voltage provided through the second input/output pad 1405 from affecting a metal layer disposed on the third substrate 1410 in the word line bonding region WLBA.

Meanwhile, in certain embodiments, the first to third input/output pads 1205, 1405 and 1406 may be selectively formed. For example, the memory device 1500 may be realized to include only the first input/output pad 1205 disposed on the first substrate 1210, to include only the second input/output pad 1405 disposed on the third substrate 1410, or to include only the third input/output pad 1406 disposed on the upper insulating layer 1401.

In some embodiments, at least one of the second substrate 1310 of the first cell region CELL1 or the third substrate 1410 of the second cell region CELL2 may be used as a sacrificial substrate and may be completely or partially removed before or after a bonding process. An additional layer may be stacked after the removal of the substrate. For example, the second substrate 1310 of the first cell region CELL1 may be removed before or after the bonding process of the peripheral circuit region PERI and the first cell region CELL1, and then, an insulating layer covering a top surface of the common source line 1320 or a conductive layer for connection may be formed. Likewise, the third substrate 1410 of the second cell region CELL2 may be removed before or after the bonding process of the first cell region CELL1 and the second cell region CELL2, and then, the upper insulating layer 1401 covering a top surface of the common source line 1420 or a conductive layer for connection may be formed.

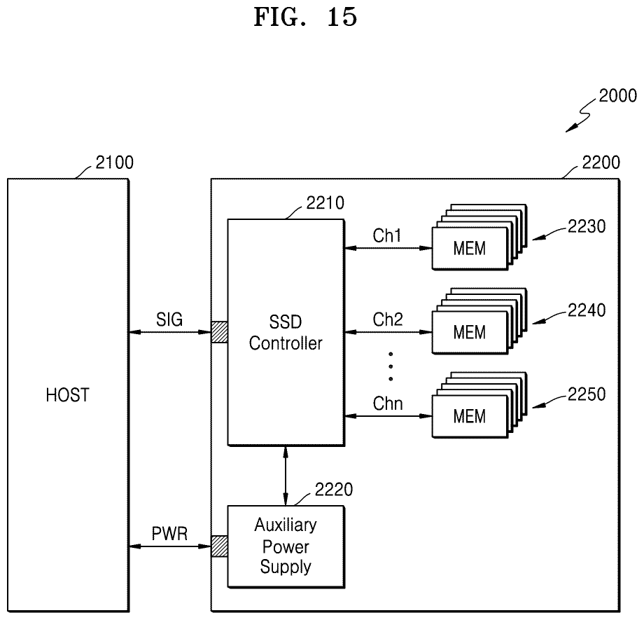

FIG. 15 is a block diagram illustrating an example in which a memory device according to embodiments is applied to an SSD system 2000.

Referring to FIG. 15, the SSD system 2000 may include a host 2100 and an SSD 2200. The SSD 2200 may exchange signals with the host 2100 through a signal connector and receive power through a power connector. The SSD 2200 may include an SSD controller 2210, an auxiliary power supply 2220, and memory devices 2230, 2240, and 2250. The memory devices 2230, 2240, and 2250 may be vertically stacked NAND flash memory devices. In this case, the SSD controller 2210, the auxiliary power supply 2220, and the memory devices 2230, 2240, and 2250 may be implemented by using the embodiments described above with reference to FIGS. 1 to 14.

While example embodiments has been particularly shown and described, it will be understood that various changes in form and details may be made therein without departing from the spirit and scope of the following claims.

What is claimed is:

1. A memory device comprising:
a memory cell array region comprising a plurality of memory cells;
a plurality of bonding pads partially overlapping the memory cell array region in a vertical direction, the plurality of bonding pads comprising a bonding pad configured to electrically connect the memory device to an external device and a non-bonding pad configured to be electrically connected to an internal circuit of the memory device;
a first test pattern form below the bonding pad and configured to output a first test output signal based on a test input signal;
a second test pattern form below the non-bonding pad and configured to output a second test output signal based on the test input signal; and
a damage detection circuit configured to output a test result signal indicating whether a lower region of the bonding pad has been damaged, based on a first number of logic level transitions of the first test output signal and a second number of logic level transitions of the second test output signal.

2. The memory device of claim 1, wherein the damage detection circuit comprises:
a first counter configured to output a first count value corresponding to transitions of the first test output signal from a high level to a low level during a first reference time period;
a second counter configured to output a second count value corresponding to transitions of the second test output signal from the high level to the low level during the first reference time period; and
a comparator configured to output the test result signal based comparing the first count value with the second count value.

3. The memory device of claim 1, wherein the bonding pad is above the memory cell array region, and
wherein at least a portion of the bonding pad overlaps at least a portion of the memory cell array region in a first direction that is the vertical direction.

4. The memory device of claim 1, wherein the non-bonding pad is disposed above the memory cell array region,
wherein at least a portion of the non-bonding pad overlaps at least a portion of the memory cell array region in a first direction that is the vertical direction, and
wherein the non-bonding pad is apart from the bonding pad in a second direction perpendicular to the first direction.

5. The memory device of claim 1, wherein the non-bonding pad is not electrically connected to the external device.

6. The memory device of claim 2, further comprising a multiplexer configured to:
select one of the second count value and a test expectation value previously input to the memory device, and
provide the selected one of the second count value and the test expectation value to the comparator.

7. The memory device of claim 1, wherein the damage detection circuit is further configured to, based on a first count value indicating the first number of logic level transitions of the first test output signal is less than a first count reference value or greater than a second count reference value, output the test result signal indicating that the lower region of the bonding pad has been damaged,
wherein the first count reference value is less than a second count value indicating a second number logic level transitions of the second test output signal, and
wherein the second count reference value is greater than the second count value.

8. The memory device of claim 7, wherein the damage detection circuit is further configured to, based on the first count value being greater than the first count reference value and less than the second count reference value, output the test result signal indicating that the lower region of the bonding pad is normal.

9. A memory device comprising:
a memory cell array region comprising a plurality of memory cells;
a plurality of bonding pads partially overlapping the memory cell array region in a vertical direction, the plurality of bonding pads comprising a bonding pad configured to electrically connect the memory device to an external device and a non-bonding pad configured to be electrically connected to an internal circuit of the memory device;
a first test pattern form below the bonding pad and configured to output a first test output signal based on a test input signal;
a second test pattern form below the non-bonding pad and configured to output a second test output signal based on the test input signal; and
a damage detection circuit configured to output a test result signal indicating whether a lower region of the bonding pad has been damaged, based on comparing a first delay time of the first test output signal with a second delay time of the second test output signal.

10. The memory device of claim 9, wherein the damage detection circuit comprises:
a first time-to-digital conversion circuit configured to output a first delay value indicating the first delay time of the first test output signal generated based on the test input signal applied during a first reference time period;
a second time-to-digital conversion circuit configured to output a second delay value indicating the second delay time of the second test output signal generated in response to the test input signal applied thereto during the first reference time period; and
a comparator configured to output the test result signal based on comparing the first delay value with the second delay value.

11. The memory device of claim 9, wherein the bonding pad is above the memory cell array region, and
wherein at least a portion of the bonding pad overlaps at least a portion of the memory cell array region in a first direction that is the vertical direction.

12. The memory device of claim 9, wherein the non-bonding pad is above the memory cell array region,
wherein at least a portion of the non-bonding pad overlaps at least a portion of the memory cell array region in a first direction that is the vertical direction, and
wherein the non-bonding pad is apart from the bonding pad in a second direction perpendicular to the first direction.

13. The memory device of claim 9, wherein the non-bonding pad is not electrically connected to the external device.

14. The memory device of claim 10, further comprising a multiplexer configured to:
select one of the second delay value and a test expectation value previously input to the memory device, and
provide the selected one of the second delay value and the test expectation value to the comparator.

15. The memory device of claim 9, wherein the damage detection circuit is further configured to, based on a first delay value indicating the first delay time of the first test output signal is less than a first delay reference value or greater than a second delay reference value, output the test result signal indicating that the lower region of the bonding pad has been damaged,
wherein the first delay reference value is less than a second delay value indicating the second delay time of the second test output signal, and
wherein the second delay reference value is greater than the second delay value.

16. The memory device of claim 15, wherein the damage detection circuit is further configured to, based on the first delay value being greater than the first delay reference value and less than the second delay reference value, output the test result signal indicating that the lower region of the bonding pad is normal.

17. A test system comprising:
a memory device; and
a test device configured to provide a test input signal to the memory device,
wherein the memory device is configured to provide, to the test device, a test result signal generated based on the test input signal, and
wherein the memory device comprises:
a memory cell array region comprising a plurality of memory cells;
a plurality of bonding pads partially overlapping the memory cell array region in a vertical direction, the plurality of bonding pads comprising a bonding pad configured to electrically connect the memory device to an external device and a non-bonding pad configured to be electrically connected to an internal circuit of the memory device;
a first test pattern form below the bonding pad and configured to output a first test output signal based on the test input signal;
a second test pattern form below the non-bonding pad and configured to output a second test output signal based on the test input signal; and
a damage detection circuit configured to output the test result signal indicating whether a lower region of the bonding pad has been damaged, based on a first number of logic level transitions of the first test output signal and a second number of logic level transitions of the second test output signal.

18. The test system of claim 17, wherein the bonding pad is above the memory cell array region, and
wherein at least a portion of the bonding pad overlaps at least a portion of the memory cell array region in a first direction that is the vertical direction.

19. The test system of claim 17, wherein the non-bonding pad is above the memory cell array region,
wherein at least a portion of the non-bonding pad overlaps at least a portion of the memory cell array region in a first direction that is the vertical direction, and
wherein the non-bonding pad is apart from the bonding pad in a second direction perpendicular to the first direction.

20. The test system of claim 17, wherein the non-bonding pad is not electrically connected to the external device.
